(19) United States
(12) Patent Application Publication
(10) Pub. No.: US 2016/0077144 A1
(43) Pub. Date: Mar. 17, 2016

(54) ELECTRONIC DEVICE

(71) Applicant: KABUSHIKI KAISHA TOSHIBA, Tokyo (JP)

(72) Inventors: Yoshihiko KURUI, Kawasaki Kanagawa (JP); Tamio IKEHASHI, Yokohama Kanagawa (JP)

(73) Assignee: KABUSHIKI KAISHA TOSHIBA, Tokyo (JP)

(21) Appl. No.: 14/643,904

(22) Filed: Mar. 10, 2015

(30) Foreign Application Priority Data
Sep. 12, 2014 (JP) 2014-186469

(51) Int. Cl. G01R 31/02; G01R 19/165; H03M 1/38

(52) U.S. Cl. CPC G01R 31/028; H03M 1/38; G01R 19/16504

(57) ABSTRACT

According to one embodiment, an electronic device includes a variable capacitor includes first and second electrodes, and indicating a first state in which a distance between the first and second electrodes is a first distance and a second state in which the distance between the first and second electrodes is a second distance shorter than the first distance, in accordance with a voltage applied between the first and second electrodes, a voltage applying circuit applying a voltage between the first and second electrodes, and a voltage detecting circuit detecting a first voltage based on an interelectrode voltage between the first and second electrodes. The variable capacitor, the voltage applying circuit and the voltage detecting circuit are provided in a same chip.

### CROSS-REFERENCE TO RELATED APPLICATIONS

This application is based upon and claims the benefit of priority from Japanese Patent Application No. 2014-186469, filed Sep. 12, 2014, the entire contents of which are incorporated herein by reference.

### FIELD

Embodiments described herein relate generally to an electronic device.

### BACKGROUND

An electronic device comprising a variable capacitor adopting micro electro mechanical systems (MEMS) formed on a semiconductor substrate has been proposed. In the variable capacitor, a distance between electrodes is varied and capacitance is also varied in accordance with a voltage applied between the electrodes. More specifically, two states, i.e., a state (pull-out state or up state) in which the distance between the electrodes is relatively long and a state (pull-in state or down state) in which the distance between the electrodes is relatively short can be set.

In such a variable capacitor, a time to shift from the pull-out state to the pull-in state, a threshold voltage at which the pull-out state is shifted to the pull-in state, a threshold voltage at which the pull-in state is shifted to the pull-out state, etc. are important parameters for evaluation of performance of the variable capacitor.

Conventionally, however, properly evaluating the performance of the variable capacitor in a short time has been difficult.

### BRIEF DESCRIPTION OF THE DRAWINGS

FIG. 1 is a block diagram showing a basic structure of an electronic device of an embodiment.

FIG. 2 is a cross-sectional view illustrating a variable capacitor according to the embodiment.

FIG. 3 is an electric circuit diagram showing a concrete structure of the electronic device of the embodiment.

FIG. 4 is a graph showing an operation to obtain a pull-in time according to the embodiment.

FIG. 5 is a table showing states of respective portions in the operation to obtain a pull-in time according to the embodiment.

FIG. 6 is a flowchart showing a method of obtaining the pull-in time according to the embodiment.

FIG. 7 is a graph showing a relationship between an input voltage and a pull-in voltage according to the embodiment.

FIG. 8 is a graph showing a principle for obtaining the pull-in voltage according to the embodiment.

FIG. 9 is a flowchart showing a method of obtaining the pull-in voltage according to the embodiment.

FIG. 10 is a graph showing a principle for obtaining a pull-out voltage according to the embodiment.

FIG. 11 is a flowchart showing a method of obtaining the pull-out voltage according to the embodiment.

### DETAILED DESCRIPTION

In general, according to one embodiment, an electronic device includes: a variable capacitor comprising first and second electrodes, and indicating a first state in which a distance between the first and second electrodes is a first distance and a second state in which the distance between the first and second electrodes is a second distance shorter than the first distance, in accordance with a voltage applied between the first and second electrodes; a voltage applying circuit applying a voltage between the first and second electrodes; and a voltage detecting circuit detecting a first voltage based on an interelectrode voltage applied between the first and second electrodes, the first voltage being used to evaluate performance of the variable capacitor, wherein the variable capacitor, the voltage applying circuit and the voltage detecting circuit are provided in a same chip.

Embodiments will be hereinafter described with reference to the accompanying drawings.

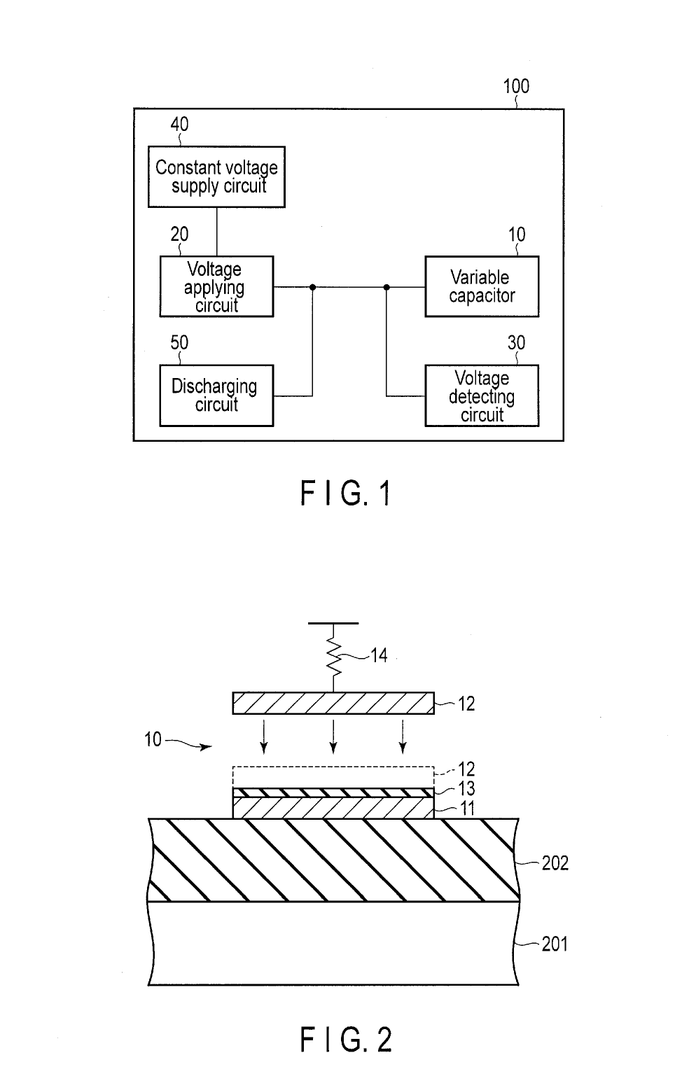

FIG. 1 is a block diagram showing a basic configuration of an electronic device according to one of the embodiments.

As shown in FIG. 1, the electronic device of the present embodiment comprises a variable capacitor 10, a voltage applying circuit 20, a voltage detecting circuit 30, a constant voltage supply circuit 40 and a discharging circuit 50. These circuits are provided in the same chip (semiconductor chip) 100. A circuit for controlling operation of the variable capacitor 10, etc. are also included in the chip 100.

FIG. 2 is a cross-sectional view illustrating a structure of the variable capacitor 10.

The variable capacitor 10 is a MEMS element formed by MEMS (micro electro mechanical systems) technology, which comprises a lower electrode (first electrode) 11, an upper electrode (second electrode) 12 opposed to the lower electrode 11, an insulating film 13 provided on the lower electrode 11, and an elastic member (spring) 14 connected to the upper electrode 12. The upper electrode 12 is supported by the elastic member 14. The variable capacitor (MEMS element) 10 is formed on an underlying region including a semiconductor substrate 201, an insulating region 201, etc.

The variable capacitor 10 is configured to indicate a first state (pull-out state, upstate) in which a distance between the lower electrode 11 and the upper electrode 12 is a first distance and a second state (pull-in state, downstate) in which the distance between the lower electrode 11 and the upper electrode 12 is a second distance shorter than the first distance, in accordance with a voltage applied between the lower electrode 11 and the upper electrode 12. In other words, the distance between the lower electrode 11 and the upper electrode 12 is varied in accordance with an electrostatic force applied between the lower electrode 11 and the upper electrode 12. Capacitance of the variable capacitor 10 is varied by varying the distance between the lower electrode 11 and the upper electrode 12.

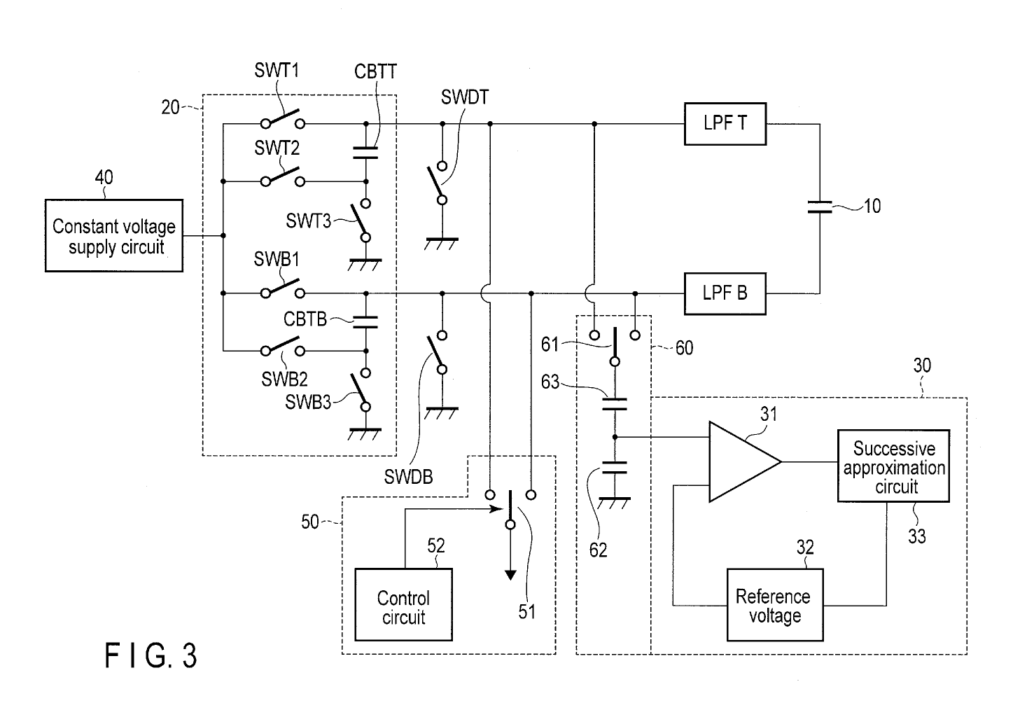

FIG. 3 is an electric circuit diagram showing a concrete configuration of the electronic device according to the embodiment.

The voltage applying circuit 20 is configured to apply the voltage between the lower electrode 11 and the upper electrode 12 of the variable capacitor 10. The voltage applying circuit 20 is constituted by a boost circuit which boosts an input voltage. A period in which the input voltage is boosted by the boost circuit is variable. In addition, the input voltage of the boost circuit is also variable.

The voltage applying circuit (boost circuit) 20 comprises switches SWT1, SWT2, SWT3, SWB1, SWB2 and SWB3, and boost capacitors CBTT and CBTB.

The switches SWT1, SWT2, and SWT3, and the boost capacitor CBTT are employed when voltage is applied to the upper electrode 12 of the variable capacitor 10. In this case, other switches SWB1, SWB2, and SWB3, and other boost capacitor CBTB do not function substantially. More specifically, the switches SWT1, SWT2, and SWT3, and the boost capacitor CBTT are set to function, and the switches SWB1, SWB2, and SWB3, and other boost capacitor CBTB are set not to function substantially, by setting a pull-down switch SWDT in an OFF state and setting a pull-down switch SWDB in an ON state.

On the other hand, the switches SWB1, SWB2, and SWB3, and the boost capacitor CBTB are employed when voltage is applied to the lower electrode 11 of the variable capacitor 10. In this case, other switches SWT1, SWT2, and SWT3, and other boost capacitor CBTT do not function substantially. More specifically, the switches SWB1, SWB2, and SWB3, and the boost capacitor CBTB are set to function, and the switches SWT1, SWT2, and SWT3, and other boost capacitor CBTT are set not to function substantially, by setting a pull-down switch SWDB in an OFF state and setting a pull-down switch SWDT in an ON state.

The voltage generated by the voltage applying circuit 20 is applied to the variable capacitor 10 via a low-pass filter LPFT or a low-pass filter LPFB. More specifically, when the voltage is applied to the upper electrode 12 of the variable capacitor 10, the voltage is applied to the upper electrode 12 of the variable capacitor 10 via the low-pass filter LPFT. When the voltage is applied to the lower electrode 11 of the variable capacitor 10, the voltage is applied to the lower electrode 11 of the variable capacitor 10 via the low-pass filter LPFB.

The voltage generated by the voltage applying circuit 20 is divided by a voltage dividing circuit 60 comprising a switch 61, and capacitors 62 and 63. More specifically, when the voltage is applied to the upper electrode 12 of the variable capacitor 10, the switch 61 is connected to the low-pass filter LPFT side. When the voltage is applied to the lower electrode 11 of the variable capacitor 10, the switch 61 is connected to the low-pass filter LPFB side. In the example shown in FIG. 3, the voltage dividing circuit 60 is connected to input sides of the low-pass filters LPFT and LPFB, but may be connected to output sides of the low-pass filters LPFT and LPFB.

The voltage detecting circuit 30 is configured to detect a voltage (first voltage) based on the interelectrode voltage applied between the lower electrode 11 and the upper electrode 12 of the variable capacitor 10. The voltage detected by the voltage detecting circuit 30 may be the interelectrode voltage itself or a voltage obtained in relation to the interelectrode voltage.

The voltage detecting circuit 30 comprises a comparator 31, a reference voltage generating circuit 32, and a successive approximation circuit (reference voltage setting circuit) 33.

A digital voltage based on the interelectrode voltage of the variable capacitor 10 is output from the voltage detecting circuit 30. In other words, the voltage detecting circuit 30 is constituted by an AD converter configured to generate the digital voltage, and the digital voltage value AD-converted by the AD converter is output from the voltage detecting circuit 30. In the present embodiment, a successive approximation type AD converter is employed as the AD converter. By employing the successive approximation type AD converter, voltage detection can be executed at high speed.

The comparator 31 compares the voltage (first voltage) divided by the voltage dividing circuit 60 with a reference voltage. The reference voltage is generated by the reference voltage generating circuit 32. The successive approximation circuit (reference voltage setting circuit) 33 is connected to an output of the comparator 31. In the successive approximation circuit 33, logic processing is executed based on the output of the comparator 31, and the reference voltage based on a logic processing result is set in the reference voltage generating circuit 32. A digital value is output from the successive approximation circuit 33, and the digital value corresponds to the digital voltage value based on the interelectrode voltage of the variable capacitor 10. Concrete operations of the voltage detecting circuit 30 will be explained below.

The comparator 31 compares the voltage (divided voltage) divided by the voltage dividing circuit 60 with the reference voltage. If the divided voltage is higher than the reference voltage, a logic output value of the comparator 31 becomes high. In the successive approximation circuit 33, the reference voltage is increased based on the logic output value of the comparator 31. If the divided voltage is lower than the reference voltage, a logic output value of the comparator 31 becomes low. In the successive approximation circuit 33, the reference voltage is reduced based on the logic output value of the comparator 31.

After that, the divided voltage is compared with the updated reference voltage, and the reference voltage is increased or reduced in accordance with the comparison result (logic output value of the comparator 31). Thus, the divided voltage is successively compared with the updated reference voltage, and the digital value obtained by the successive comparison is output from the successive approximation circuit 33 as a digital voltage value. In other words, the digital voltage value corresponding to the divided voltage is output from the successive approximation circuit 33.

The constant voltage supply circuit 40 supplies a constant voltage to the voltage applying circuit 20 (boost circuit), and is constituted by a charge pump circuit.

The discharging circuit 50 discharges charge stored in the variable capacitor. The discharging operation is constant current discharging. The discharging circuit 50 comprises a switch 51 and a control circuit 52 configured to control the switch 51. More specifically, when the voltage is applied to the upper electrode 12 of the variable capacitor 10, the switch 51 is connected to the low-pass filter LPFT side and the charge stored in the upper electrode 12 is discharged. When the voltage is applied to the lower electrode 11 of the variable capacitor 10, the switch 51 is connected to the low-pass filter LPFB side and the charge stored in the lower electrode 11 is discharged.

In the electronic device of the present embodiment, as described above, the variable capacitor 10, the voltage applying circuit 20, the voltage detecting circuit 30, the constant voltage supply circuit 40 and the discharging circuit 50 are provided in a single chip (semiconductor chip) 100, and what is called a BIST (built in self test) circuit is constituted.

Next, operations executed in the electronic device shown in FIG. 1, FIG. 2 and FIG. 3 will be explained.

A pull-in time (pull-in period), a pull-in voltage and a pull-out voltage are important as parameters to evaluate performance of the variable capacitor.

The pull-in voltage is a threshold voltage for the variable capacitor to shift from the up state (pull-out state) to the down state (pull-in state). When a voltage equal to or greater than the pull-in voltage is applied between the electrodes of the variable capacitor, the variable capacitor shifts from the up state to the down state.

The pull-out voltage is a threshold voltage for the variable capacitor to shift from the down state (pull-in state) to the up state (pull-out state). When a voltage equal to or smaller than the pull-out voltage is applied between the electrodes of the variable capacitor, the variable capacitor shifts from the down state to the up state.

The pull-in time is a time for the variable capacitor to shift from the pull-out state to the pull-in state, and a threshold time from applying a voltage equal to or greater than the pull-in voltage between the electrodes and to actually shifting to the pull-in state. By applying the voltage equal to or greater than the pull-in voltage for a time equal to or longer than the pull-in time, the variable capacitor shifts from the up state to the down state.

In the following explanations, the lower electrode 11 of the variable capacitor 10 is fixed to a constant potential (for example, ground potential) and the voltage is applied to the upper electrode 12 of the variable capacitor 10. Therefore, the switch SWDB in FIG. 3 is in the on state, and the lower electrode 11 of the variable capacitor 10 is fixed to the ground potential.

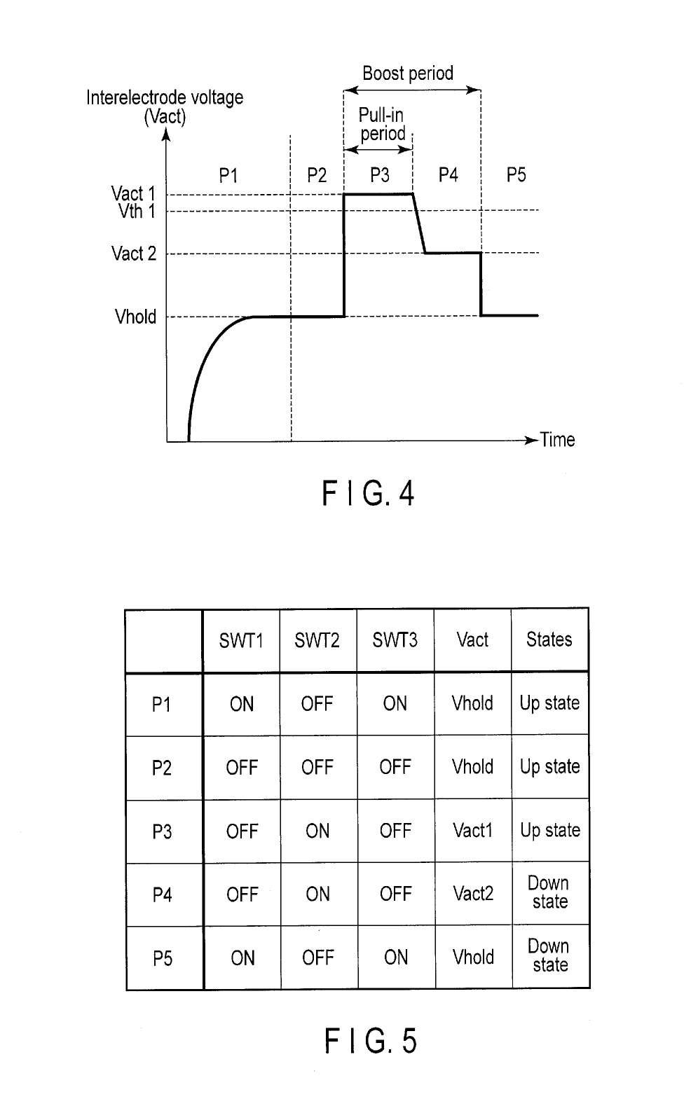

First, a method of obtaining the pull-in time will be explained. FIG. 4 is a graph showing an operation to obtain the pull-in time. A lateral axis indicates a time while a vertical axis indicates the interelectrode voltage (Vact) of the variable capacitor. FIG. 5 is a table showing a state at each portion in the operation to obtain the pull-in time.

In period P1, the switch SWT1 in FIG. 3 is in the on state, the switch SWT2 is in the off state, and the switch SWT3 is in the on state. For this reason, the boost capacitor CBTT is charged with an output voltage Vhold of the constant voltage supply circuit 40. The interelectrode voltage Vact of the variable capacitor is therefore voltage Vhold. Since the voltage Vhold is lower than the pull-in voltage (threshold voltage Vth1), the variable capacitor 10 is in the up state.

In period P2, the switch SWT1 is in the off state, the switch SWT2 is in the off state, and the switch SWT3 is in the off state. For this reason, the boost capacitor CBTT is in a floating state. Therefore, the interelectrode voltage Vact of the variable capacitor 10 is maintained as the voltage Vhold, and the variable capacitor 10 is maintained in the up-state.

Period P3 and period P4 are boost periods in which the boosting operation is executed at the voltage applying circuit (boost circuit) 20. More specifically, the periods will be explained below.

In period P3, the switch SWT1 is in the off state, the switch SWT2 is in the on state, and the switch SWT3 is in the off state. For this reason, the voltage Vhold of the voltage applying circuit (boost circuit) 20 is boosted by the boost capacitor CBTT, and the output voltage of the voltage applying circuit 20 is raised. At this time, the charge of the boost capacitor CBTT is distributed to the variable capacitor 10 and a parasitic capacitor (not shown). As a result, the interelectrode voltage Vact1 becomes higher than the pull-in voltage (threshold voltage Vth1).

However, even if the interelectrode voltage becomes higher than the pull-in voltage, the variable capacitor 10 does not immediately shift to the down state. In other words, the variable capacitor 10 does not shift to the down state unless the voltage equal to or greater than the pull-in period and equal to or greater than the pull-in voltage is applied between the electrodes. Therefore, in period P3, the variable capacitor 10 is in the up state, and the interelectrode voltage Vact1 can be expressed as follows.

Vact1=Vhold+{Cbt/(Cbt+Cup+Cpara)}×Vhold

where Cbt indicates the capacitance of the boost capacitor CBTT, Cup indicates the capacitance of the variable capacitor 10 in the up state, and Cpara indicates the parasitic capacitance.

In period P4, too, similarly to period P3, the switch SWT1 is in the off state, the switch SWT2 is in the on state, and the switch SWT3 is in the off state. However, when the pull-in period ends in period P3 and period P3 shifts to period P4, the variable capacitor 10 shifts from the up state to the down state. As a result, the capacitance of the variable capacitor 10 is increased. Thus, in period P4, interelectrode voltage Vact2 of the variable capacitor 10 can be expressed as follows.

Vact2=Vhold+{Cbt/(Cbt+Cdown+Cpara)}×Vhold

where Cdown indicates the capacitance of the variable capacitor 10 in the down state.

Incidentally, the interelectrode voltage Vact2 becomes lower than the pull-in voltage, in period P4 but, in the down state, the variable capacitor does not shift to the up state unless the interelectrode voltage becomes equal to or lower than the pull-out voltage. Thus, in period P4, the down state is maintained even if the interelectrode voltage Vact2 is lower than the pull-in voltage.

In period P5, the switch SWT1 is in the on state, the switch SWT2 is in the off state, and the switch SWT3 is in the on state. Therefore, the interelectrode voltage Vact of the variable capacitor 10 is the voltage Vhold, similarly to period P1. The voltage Vhold is also lower than the pull-in voltage but higher than the pull-out voltage. In period P5, too, the down state is maintained.

The pull-in period can be obtained by executing the above-described sequence. In other words, when period P3 shifts to period P4, the variable capacitor 10 shifts from the up state to the down state, and the interelectrode voltage drops. Period P3 therefore corresponds to the pull-in period.

As described above, the variable capacitor 10 shifts from the up state to the down state, by applying the input voltage boosted by the boost circuit between the lower electrode 11 and the upper electrode 12 for a period equal to or longer than the pull-in period (threshold period). The pull-in period (threshold period) can be therefore obtained by obtaining the first voltage based on the interelectrode voltage (divided voltage of the voltage dividing circuit 60 in the example of FIG. 3) by the voltage detecting circuit 30.

Incidentally, the boost period equal to or longer than the pull-in period needs to be set to obtain the pull-in period. However, it is often undesirable to make the boost period longer than needed.

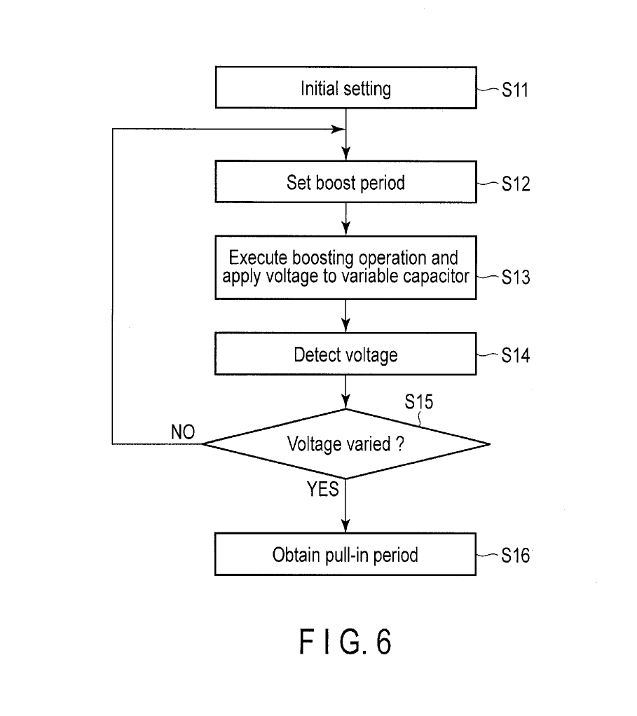

FIG. 6 is a flowchart showing a method of obtaining the pull-in period in the short boost period.

The method shown in the flowchart of FIG. 6 is executed by setting the state inside the chip 100 by a program outside the chip 100.

First, predetermined initial setting is executed (S11). Next, the boost period is set (S12). Subsequently, the boosting operation is executed in the set boost period and the voltage equal to or higher than the pull-in voltage is applied between the electrodes of the variable capacitor 10 (S13). The voltage based on the interelectrode voltage is detected by the voltage detecting circuit 30 (S14). The detected voltage (digital voltage) is preliminarily stored in an inner register. Furthermore, it is determined whether the detected voltage is varied or not, based on the detection result of the voltage detecting circuit 30 (S15). In other words, it is determined whether the detected voltage makes variation based on the shift from the up state to the down state (i.e., corresponds to the variation based on the shift from period P3 to period P4 in FIG. 4).

If it is determined in step S15 that the detected voltage is not varied, the processing returns to step S12. In step S12, the boost period is extended by a predetermined length, and a new boost period is set. Then, steps S13 to S15 are executed in the new boost period. Thus, steps S13 to S15 are executed while extending the boost period step by step until it is determined in step S15 that the voltage is varied.

If it is determined in step S15 that the voltage is varied, the point in variation of the detected voltage is regarded as an end point of the pull-in period. The pull-in period is thereby obtained (S16). More specifically, the boost period set at this point is regarded as the pull-in period.

The pull-in period can be thus obtained in a short boost period.

Next, a method of obtaining the pull-in voltage will be explained.

The variable capacitor shifts from the pull-out state (up state) to the pull-in state (down state) when the interelectrode voltage of the variable capacitor 10 becomes equal to or greater than the pull-in voltage (first threshold voltage) by boosting the input voltage by the voltage applying circuit (boost circuit) 20. The pull-in voltage can be therefore obtained by detecting the voltage (first voltage) based on the interelectrode voltage by the voltage detecting circuit 30.

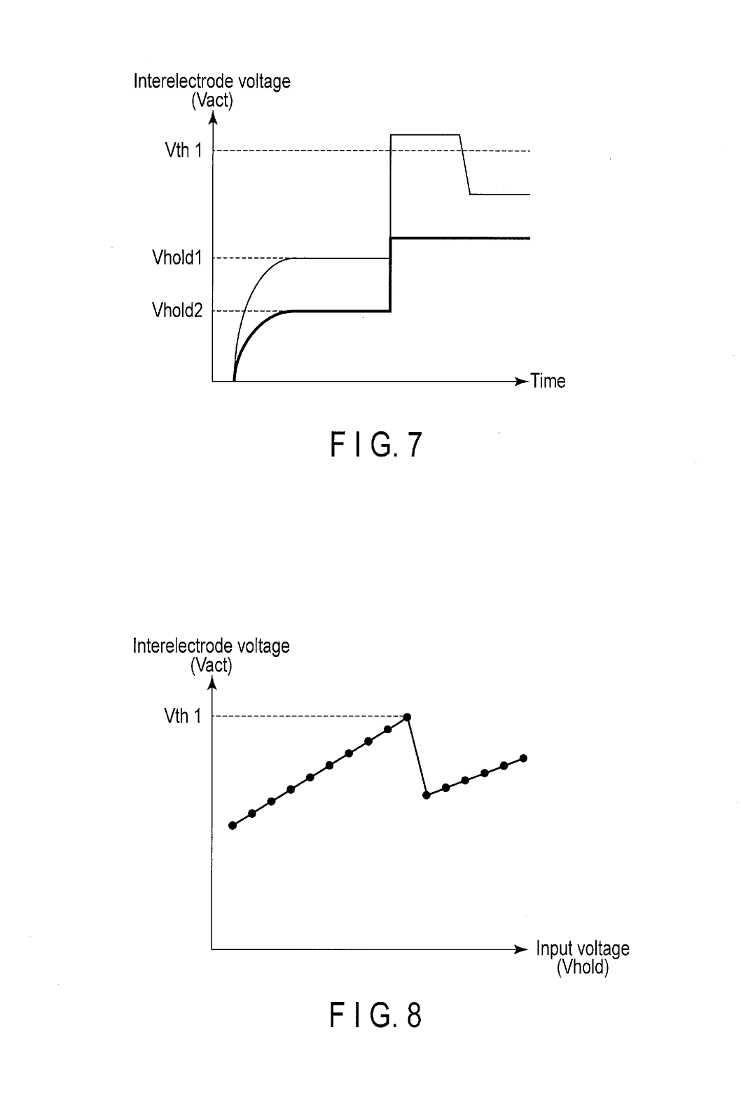

FIG. 7 is a graph showing a relationship between the input voltage and the pull-in voltage. A lateral axis indicates a time while a vertical axis indicates the interelectrode voltage (Vact) of the variable capacitor.

As understood from the above explanations, the variable capacitor 10 does not shift from the up state to the down state unless the voltage equal to or greater than the pull-in voltage is applied between the electrodes. In the example shown in FIG. 7, when the input voltage of the voltage applying circuit (boost circuit) 20 is Vhold1, the variable capacitor 10 shifts to the down state since the voltage equal to or greater than the pull-in voltage (first threshold voltage Vth1) is applied to the variable capacitor 10 by the boosting operation. When the input voltage of the voltage applying circuit (boost circuit) 20 is Vhold2, the variable capacitor 10 cannot shift to the down state since the voltage equal to or greater than the pull-in voltage (first threshold voltage Vth1) is not applied to the variable capacitor 10. In addition, when the variable capacitor 10 shifts from the up state to the down state, the interelectrode voltage drops as shown in FIG. 7.

Therefore, the pull-in voltage can be obtained if the interelectrode voltage is increased step by step by increasing the input voltage Vhold step by step and the interelectrode voltage is plotted after executing the boosting operation.

FIG. 8 is a graph showing a principle of obtaining the pull-in voltage. A lateral axis indicates the input voltage Vhold of the voltage applying circuit (boost circuit) 20 while a vertical axis indicates the interelectrode voltage (Vact) obtained after executing the boosting operation. The boosting operation period is set to be sufficiently longer than the pull-in period.

As shown in FIG. 8, the interelectrode voltage Vact increases as the input voltage Vhold increases, until the interelectrode voltage reaches the pull-in voltage (first threshold voltage Vth1). However, when the interelectrode voltage reaches the pull-in voltage, the capacitance of the variable capacitor 10 increases, and the interelectrode voltage is lower than the interelectrode voltage at the previous measurement point since the variable capacitor 10 shifts from the up state to the down state. Therefore, when the interelectrode voltage becomes maximum, the interelectrode voltage can be substantially regarded as the pull-in voltage.

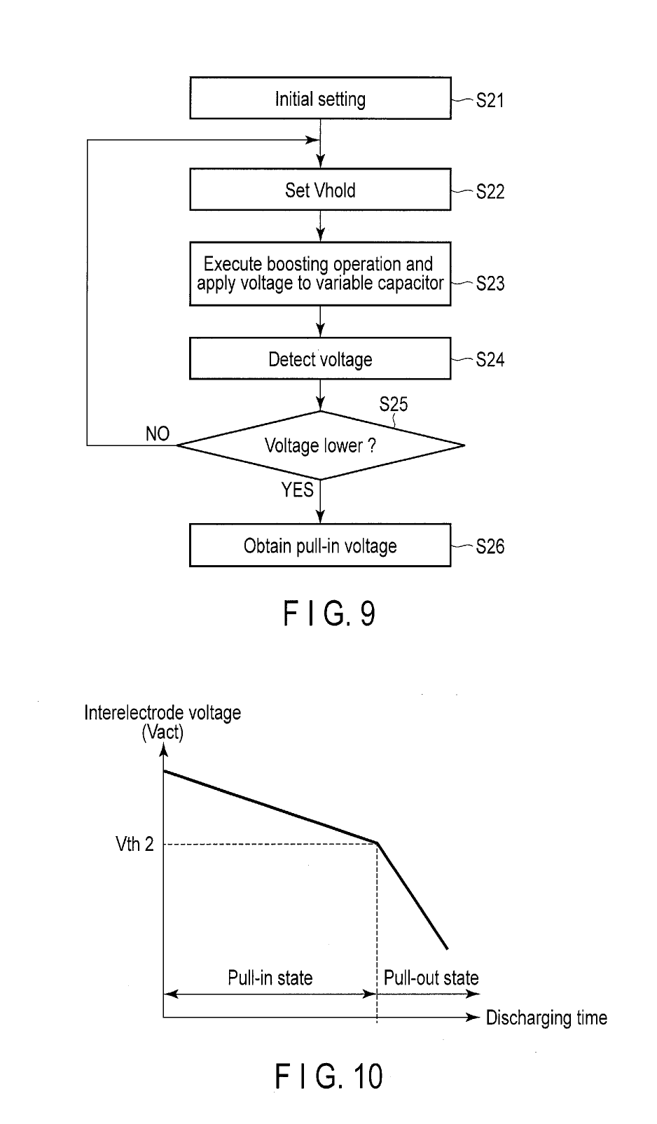

FIG. 9 is a flowchart showing a method of obtaining the pull-in voltage. The method shown in the flowchart of FIG. 9 is executed by setting the state inside the chip 100 by a program outside the chip 100.

First, predetermined initial setting is executed (S21). Next, the input voltage Vhold of the boost circuit is set (S22). Subsequently, the boosting operation is executed with the set input voltage Vhold and the boost voltage is applied to the variable capacitor 10 (S23). At this time, the boosting operation is executed for a sufficient period longer than the pull-in period. The voltage based on the interelectrode voltage is detected by the voltage detecting circuit 30 (S24). In other words, the voltage to be obtained after applying the boost voltage is detected (S24). The detected voltage (digital voltage) is preliminarily stored in an inner register.

Next, it is determined whether the detected voltage is lower than the voltage detected at the previous detection point or not, based on the detection result of the voltage detecting circuit 30 (S25).

If it is determined in step S25 that the detected voltage is not lower than the voltage detected at the previous detection point, the processing returns to step S22. In step S22, the input voltage Vhold is increased by a predetermined voltage, and a new input voltage Vhold is set. Then, steps S23 to S25 are executed with the new input voltage Vhold. Thus, steps S23 to S25 are executed while increasing the input voltage Vhold step by step until it is determined in step S25 that the detected voltage is lower than the voltage detected at the previous measurement point.

If it is determined in step S25 that the detected voltage is lower than the voltage detected at the previous measurement point, the interelectrode voltage obtained at the previous measurement point is regarded as the pull-in voltage. The pull-in voltage is thereby obtained (S26). More specifically, the pull-in voltage can be obtained by preliminarily obtaining a relationship between the interelectrode voltage and the detected voltage of the voltage detecting circuit 30.

The pull-in voltage can be thus obtained.

Next, a method of obtaining the pull-out voltage will be explained.

The variable capacitor 10 shifts from the pull-in state (down state) to the pull-out state (up state) when the voltage applied between the electrodes of the variable capacitor 10 becomes equal to or lower than the pull-out voltage (second threshold voltage) by discharging the charge stored in the variable capacitor 10 by the discharging circuit 50 shown in FIG. 1 and FIG. 3. The pull-out voltage can be therefore obtained by detecting the voltage (first voltage) based on the interelectrode voltage by the voltage detecting circuit 30.

FIG. 10 is a graph showing a principle of obtaining the pull-out voltage. A lateral axis indicates a discharging time while a vertical axis indicates the interelectrode voltage (Vact) of the variable capacitor 10.

When the variable capacitor 10 is in the pull-in state (down state), if the charge with which the variable capacitor 10 is charged is discharged by the constant current circuit, the interelectrode voltage of the variable capacitor 10 is reduced at a constant rate. When the variable capacitor 10 shifts from the pull-in state (down state) to the pull-out state (up state), the capacitance of the variable capacitor 10 is reduced. For this reason, the rate of reduction of the interelectrode voltage becomes great in the pull-out state. Therefore, when the rate of reduction of the interelectrode voltage is varied, the interelectrode voltage can be regarded as the pull-out voltage (second threshold voltage Vth2).

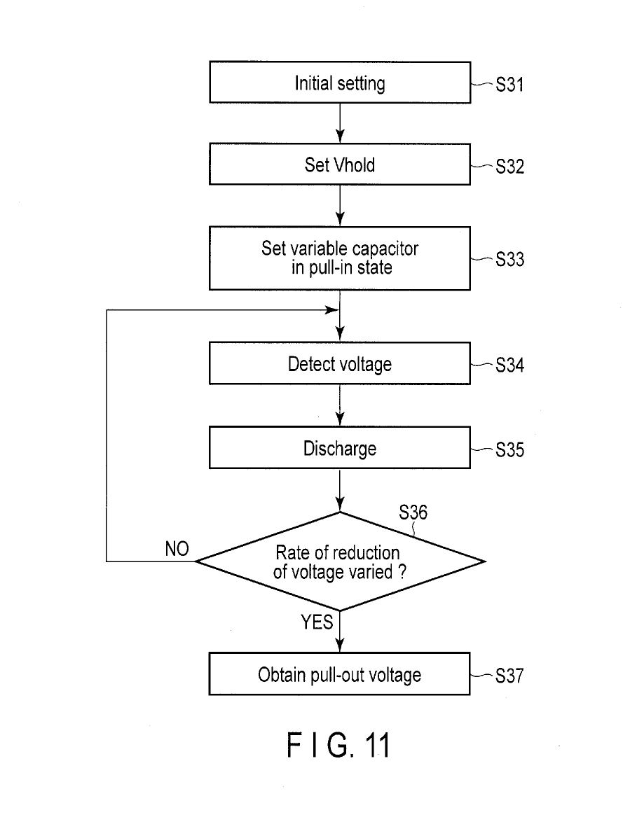

FIG. 11 is a flowchart showing a method of obtaining the pull-out voltage. The method shown in the flowchart of FIG. 11 is executed by setting the state inside the chip 100 by a program outside the chip 100.

First, predetermined initial setting is executed (S31). Next, the input voltage Vhold of the boost circuit is set (S32). Subsequently, the boosting operation is executed with the set input voltage Vhold and the variable capacitor 10 is set in the pull-in state (down state) (S33). The voltage based on the interelectrode voltage is detected by the voltage detecting circuit 30 (S34). The detected voltage (digital voltage) is preliminarily stored in an inner register. The charge with which the variable capacitor 10 is charged is discharged for a predetermined time by the discharging circuit 50 (S35). More specifically, constant current discharging is executed for a predetermined time.

Next, it is determined whether the rate of reduction of the interelectrode voltage is varied or not, based on the detection result of the voltage detecting circuit 30 (S36).

If it is determined in step S36 that the rate of reduction of the interelectrode voltage is not varied, the processing returns to step S34. Then, steps S34 to S36 are executed. In other words, the charge with which the variable capacitor 10 is charged is discharged again with a constant current for a predetermined time, in step S35. Thus, steps S34 to S36 are executed while repeating the discharging operation until it is determined in step S36 that the rate of reduction of the interelectrode voltage is varied.

If it is determined in step S36 that the rate of reduction of the interelectrode voltage is varied, the interelectrode voltage is regarded as the pull-out voltage at the time when the rate of reduction of the interelectrode voltage is varied. The pull-out voltage is thereby obtained (S37). More specifically, the pull-out voltage can be obtained by preliminarily obtaining a relationship between the interelectrode voltage and the detected voltage of the voltage detecting circuit 30.

The pull-out voltage can be thus obtained.

According to the present embodiment, as described above, the variable capacitor (MEMS element) 10, the voltage applying circuit 20 which applies the voltage between the electrodes of the variable capacitor 10, the voltage detecting circuit 30 which detects the voltage based on the interelectrode voltage, etc. are provided in the same chip 100. For this reason, the voltage based on the interelectrode voltage required to determine important parameters (pull-in period, pull-in voltage, pull-out voltage, etc.) for evaluation of the performance of the variable capacitor can be detected based on the operations in the chip 100. The performance of the variable capacitor 10 can be therefore properly evaluated based on the voltage detected by the voltage detecting circuit 30 in the chip 100. For example, the parameters (pull-in period, pull-in voltage, pull-out voltage, etc.) can be properly obtained in a short time by outputting the voltage detected by the voltage detecting circuit 30 as the digital voltage.

If a method of measuring the interelectrode voltage by an oscilloscope is employed, introduction of the method as a performance evaluation method at mass production is difficult. By adopting the method of the present embodiment, however, the performance of the variable capacitor can be properly evaluated in a short time at mass production.

In the above explanations, the lower electrode 11 of the variable capacitor 10 is fixed to a constant potential (for example, ground potential) and the voltage is applied to the upper electrode 12 of the variable capacitor 10. However, when the upper electrode 12 of the variable capacitor 10 is fixed to a constant potential (for example, ground potential) and the voltage is applied to the lower electrode 11 of the variable capacitor 10, the same operations as those in the above embodiment can also be executed. More specifically, the switch SWDT in FIG. 3 is set in the on state, and the upper electrode 12 of the variable capacitor 10 is fixed to the ground potential. Then, the switches SWB1, SWB2 and SWB3 of the lower electrode 11 side may be controlled similarly to the switches SWT1, SWT2 and SWT3 of the upper electrode 12 side in the above embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic device comprising:
a variable capacitor comprising first and second electrodes, and indicating a first state in which a distance between the first and second electrodes is a first distance and a second state in which the distance between the first and second electrodes is a second distance shorter than the first distance, in accordance with a voltage applied between the first and second electrodes;
a voltage applying circuit applying a voltage between the first and second electrodes; and
a voltage detecting circuit detecting a first voltage based on an interelectrode voltage applied between the first and second electrodes, the first voltage being used to evaluate performance of the variable capacitor,
wherein the variable capacitor, the voltage applying circuit and the voltage detecting circuit are provided in a same chip.

2. The device of claim 1, wherein
a digital voltage based on the interelectrode voltage is output from the voltage detecting circuit.

3. The device of claim 2, wherein
the voltage detecting circuit comprises an AD converter for generating the digital voltage.

4. The device of claim 3, wherein
the AD converter is a successive approximation type AD converter.

5. The device of claim 1, wherein
the voltage detecting circuit comprises:
a comparator comparing the first voltage with a reference voltage;
a reference voltage generating circuit generating the reference voltage; and
a reference voltage setting circuit setting the reference voltage based on an output of the comparator.

6. The device of claim 1, wherein
the interelectrode voltage drops when the variable capacitor shifts from the first state to the second state.

7. The device of claim 1, wherein
the voltage applying circuit comprises a boost circuit boosting an input voltage.

8. The device of claim 7, wherein
a period for boosting the input voltage by the boost circuit is variable.

9. The device of claim 7, wherein
the variable capacitor shifts from the first state to the second state by applying the input voltage boosted by the boost circuit, between the first and second electrodes, for a period equal to or longer than a threshold period.

10. The device of claim 9, wherein
the voltage detecting circuit detects the first voltage to obtain the threshold period.

11. The device of claim 10, wherein
the threshold period is obtained by increasing a period for boosting the input voltage by the boost circuit step by step.

12. The device of claim 7, wherein
the input voltage of the boost circuit is variable.

13. The device of claim 7, wherein
the variable capacitor shifts from the first state to the second state when the voltage applied between the first and second electrodes becomes equal to or higher than a first threshold voltage by boosting the input voltage by the boost circuit.

14. The device of claim 13, wherein
the voltage detecting circuit detects the first voltage to obtain the first threshold voltage.

15. The device of claim 14, wherein
the first threshold voltage is obtained by increasing the voltage applied between the first and second electrodes step by step.

16. The device of claim 7, further comprising
a constant voltage supply circuit provided in the chip and supplying a constant voltage to the boost circuit.

17. The device of claim 16, wherein
the constant voltage supply circuit comprises a charge pump circuit.

18. The device of claim 1, further comprising
a discharging circuit provided in the chip and discharging charge stored in the variable capacitor.

19. The device of claim 18, wherein
the variable capacitor shifts from the second state to the first state when the voltage applied between the first and second electrodes becomes equal to or lower than a second threshold voltage by discharging the charge stored in the variable capacitor by the discharging circuit.

20. The device of claim 19, wherein
the voltage detecting circuit detects the first voltage to obtain the second threshold voltage.
